(19) United States
(12) Patent Application Publication
(10) Pub. No.: US 2026/0150306 A1
(43) Pub. Date: May 28, 2026

(54) HIGH DENSITY MIM CAPACITOR INTEGRATION

(71) Applicant: INTERNATIONAL BUSINESS MACHINES CORPORATION, ARMONK, NY (US)

(72) Inventors: Sarabjot Singh, Albany, NY (US); Ruilong Xie, Niskayuna, NY (US); Tao Li, Slingerlands, NY (US); Qianwen Chen, Fort Collins, CO (US); Joshua Mark Rubin, Albany, NY (US)

(21) Appl. No.: 18/958,876

(22) Filed: Nov. 25, 2024

(51) Int. Cl. H01L 27/06; H01L 29/78

(52) U.S. Cl. CPC H10D 1/042; H10D 1/716; H10D 30/62; H10D 84/811

(57) ABSTRACT

A metal-insulator-metal (MIM) capacitor includes a serpentine structure that includes a first serpentine dielectric layer, a serpentine metal layer, and a second serpentine dielectric layer. The serpentine metal layer is located between the first serpentine dielectric layer and the second serpentine dielectric layer. A frontside metal layer located on a first side of the serpentine structure, and the frontside metal layer extends into a plurality of valleys located first side of the serpentine structure. A backside metal layer located on a second side of the serpentine structure and the backside metal layer extends into a plurality of valleys located on the second side of the serpentine structure.

### BACKGROUND

The present invention generally relates to the field of microelectronics, and more particularly to forming a MIM capacitor.

Nanosheet and FinFET are the lead device architecture in continuing CMOS scaling. However, technology has shown issues when scaling down such that as the devices become smaller and closer together, they are interfering with each other. With the decreasing scale it has become more important to form other components simultaneously with the nanosheet or FinFET transistors.

### BRIEF SUMMARY

Additional aspects and/or advantages will be set forth in part in the description which follows and, in part, will be apparent from the description, or may be learned by practice of the invention.

A metal-insulator-metal (MIM) capacitor includes a serpentine structure that includes a first serpentine dielectric layer, a serpentine metal layer, and a second serpentine dielectric layer. The serpentine metal layer is located between the first serpentine dielectric layer and the second serpentine dielectric layer. A frontside metal layer located on a first side of the serpentine structure, and the frontside metal layer extends into a plurality of valleys located first side of the serpentine structure. A backside metal layer located on a second side of the serpentine structure and the backside metal layer extends into a plurality of valleys located on the second side of the serpentine structure.

A metal-insulator-metal (MIM) capacitor includes a serpentine structure that includes a first serpentine dielectric layer, a serpentine metal layer, and a second serpentine dielectric layer. The serpentine metal layer is located between the first serpentine dielectric layer and the second serpentine dielectric layer. A frontside metal layer located on a first side of the serpentine structure, and the frontside metal layer extends into a plurality of valleys located first side of the serpentine structure. A backside metal layer located on a second side of the serpentine structure and the backside metal layer extends into a plurality of valleys located on the second side of the serpentine structure. A first electrode connected to the frontside metal layer and the backside metal layer. A second electrode connected to the serpentine metal layer.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a top-down view of a FinFET region and a MIM region, in accordance with the embodiment of the present invention.

FIG. 2 illustrates a cross-section X of the MIM region, in accordance with the embodiment of the present invention.

FIG. 3 illustrates a cross-section X of the MIM region after the formation of the fins, in accordance with the embodiment of the present invention.

FIG. 4 illustrates a cross-section X of the MIM region after the formation of the serpentine structure and the frontside metal layer, in accordance with the embodiment of the present invention.

FIG. 5 illustrates a cross-section X of the MIM region after the formation of a frontside electrode trench, in accordance with the embodiment of the present invention.

FIG. 6 illustrates a cross-section X of the MIM region after the formation of a serpentine spacer and the frontside electrode, in accordance with the embodiment of the present invention.

FIG. 7 illustrates a cross-section X of the MIM region after additional processing, in accordance with the embodiment of the present invention.

FIG. 8 illustrates a cross-section X of the MIM region after initial backside processing, in accordance with the embodiment of the present invention.

FIG. 9 illustrates a cross-section X of the MIM region after formation of the backside metal layer, in accordance with the embodiment of the present invention.

FIG. 10 illustrates a cross-section X of the MIM region after additional processing, in accordance with the embodiment of the present invention.

FIG. 11 illustrates a cross-section X of the MIM region that illustrates an alternative wiring scenario, in accordance with the embodiment of the present invention.

FIG. 12 illustrates a cross-section X of the MIM region that illustrates an alternative wiring scenario, in accordance with the embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art o affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will be packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout. The present invention is directed towards forming a metal-insulator-metal (MIM) capacitor on the same wafer/chip as a FinFET transistor structure. The present invention takes advantage of the fins that were created for the FinFET transistor in the formation of the MIM capacitor. The present invention forms a serpentine structure over the fins in the MIM region, where the serpentine structure includes a first dielectric layer, a serpentine metal layer, and a second dielectric layer. A frontside metal layer is formed on top of the second dielectric layer, so that the first MIM capacitor is formed between the serpentine metal layer, the second dielectric layer, and the frontside metal layer. The wafer is flipped over for backside processing in the FinFET region which also allows for backside processing of the MIM region. The underlying layers are removed in the MIM region which also removes the fins in the MIM region. The removal of the fins creates a plurality of trenches or valleys within the serpentine structure. A backside metal layer is formed, where the backside metal layer includes a plurality of protrusions, teeth, or fins that extend into the serpentine structure. A second MIM capacitor is formed from the serpentine metal layer, the first dielectric layer, and the backside metal layer. Connections to the frontside metal layer, the serpentine metal layer, and the backside metal layer of the first MIM capacitor and the second MIM capacitor can be located in the frontside region, the backside region, or a combination thereof.

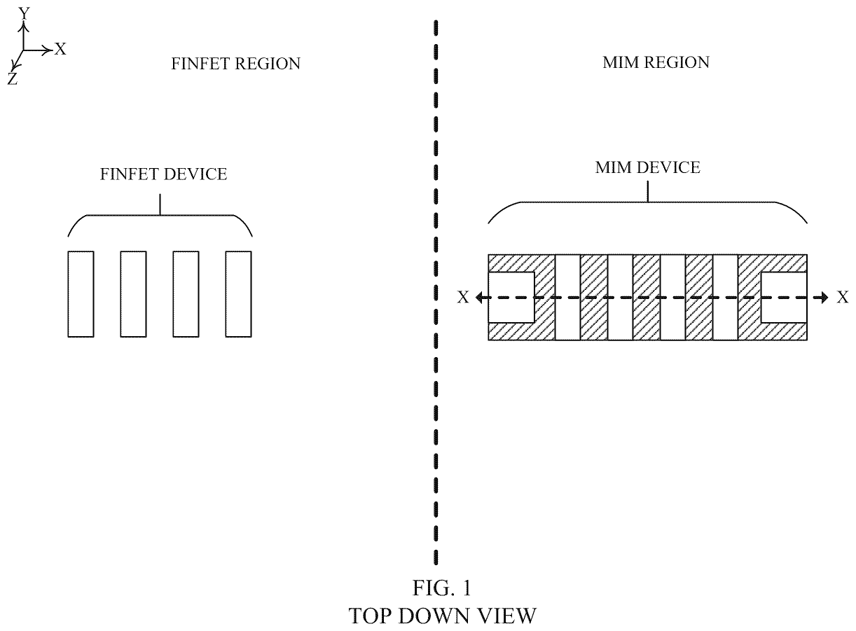

FIG. 1 illustrates a top-down view of a FinFET region and a MIM region, in accordance with the embodiment of the present invention. The FinFET region and the MIM region are located on the same wafer. The FinFET region includes a FinFET device and the necessary connections (frontside and backside) for the FinFET device. The MIM region includes the MIM device. Cross-section X extends perpendicularly to the fin direction.

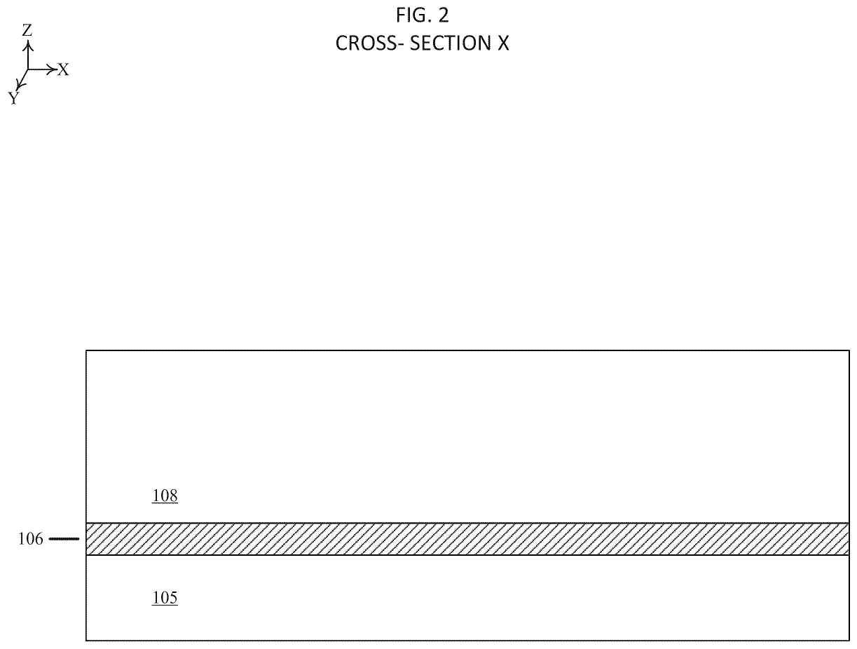

Referring now to FIG. 2, a structure is shown during an intermediate step of a method of fabricating the MIM capacitance device after forming the initial layers, according to an embodiment of the invention.

FIG. 2 illustrates the MIM device after the formation of the initial layers. The initial layers include a first substrate 105, the etch stop 106 and the second substrate 108. The first substrate 105 and the second substrate 108 can be, for example, a material including, but not necessarily limited to, silicon (Si), silicon germanium (SiGe), Si:C (carbon doped silicon), carbon doped silicon germanium (SiGe:C), III-V, II-V compound semiconductor or another like semiconductor. In addition, multiple layers of semiconductor materials can be used as the semiconductor material of the first substrate 105 and the second substrate 108. In some embodiments, first substrate 105 and the second substrate 108 includes both semiconductor materials and dielectric materials. The semiconductor first substrate 105 and the second substrate 108 may also comprise an organic semiconductor or a layered semiconductor such as, for example, Si/SiGe, a silicon-on-insulator or a SiGe-on-insulator. A portion or the entire semiconductor first substrate 105 and the second substrate 108 may also be comprised of an amorphous, polycrystalline, or monocrystalline. The semiconductor first substrate 105 and the second substrate 108 may be doped, undoped or contain doped regions and undoped regions therein.

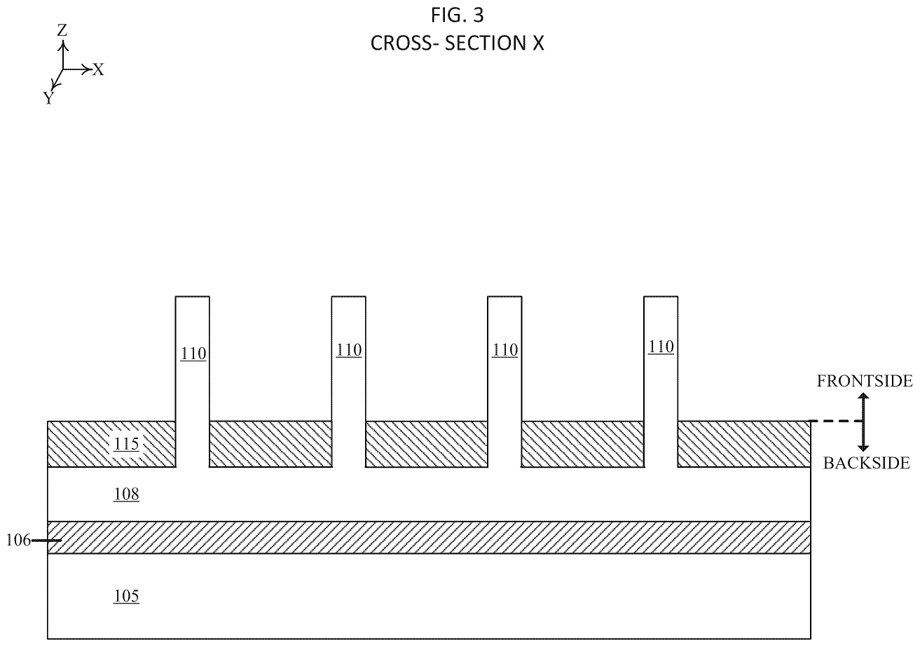

FIG. 3 illustrates the processing stage after the formation of fins 110. The second substrate 108 located in the FinFET region and the MIM region is etched to form a plurality of fins 110. A shallow trench isolation layer 115 is formed around the base of each of the fins 110. The fins 110 that are utilized in the FinFET will assist in the formation of the MIM capacitance device.

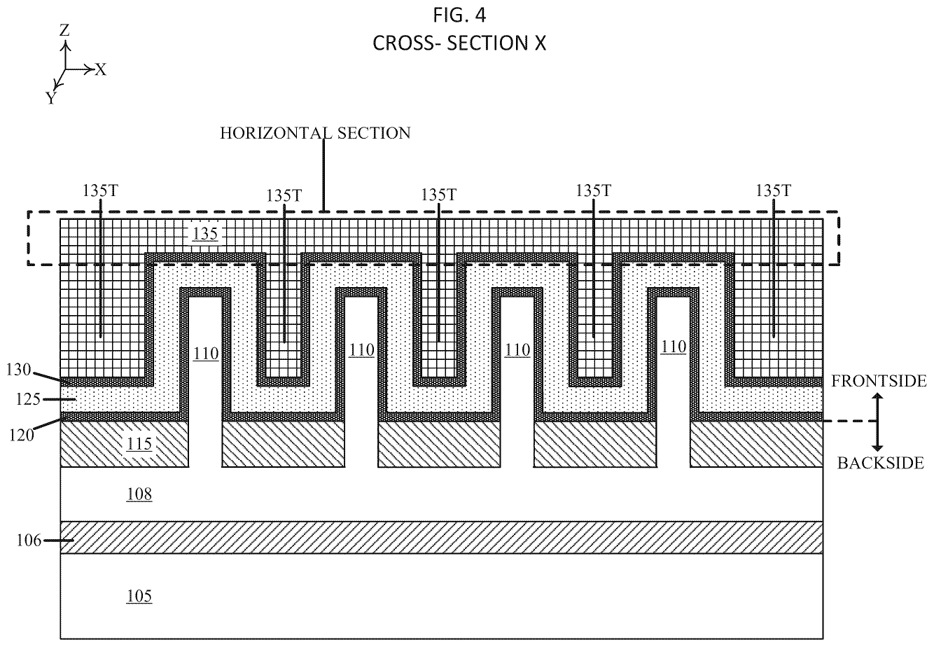

FIG. 4 illustrates the processing stage after the formation of the serpentine structure and the frontside metal layer 135. The serpentine structure includes a first dielectric layer 120, the serpentine metal layer 125, and the second dielectric layer 130. A first dielectric layer 120 is formed on top of the shallow trench isolation layer 115 and along the exposed surfaces of each of the fins 110. The first dielectric layer 120 has a hill and valley or serpentine profile as illustrated by cross-section X of MIM capacitance device (i.e., the cross-section perpendicular to the fin 110 direction). The first dielectric layer 120 is in direct contact with the shallow trench isolation layer 115 and each of the fins 110. The first dielectric layer 120 is comprised of a first dielectric material. Serpentine metal layer 125 is formed on top of the first dielectric layer 120. Serpentine metal layer 125 has a hill and valley or serpentine profile that copies the profile of the first dielectric layer 120 as illustrated by cross-section X of MIM capacitance device (i.e., the cross-section perpendicular to the fin 110 direction). Serpentine metal layer 125 can be comprised of a first conductive metal material. A second dielectric layer 130 is formed on top of the serpentine metal layer 125. The second dielectric layer 130 has a hill and valley or serpentine profile as illustrated by cross-section X of MIM capacitance device (i.e., the cross-section perpendicular to the fin 110 direction). The second dielectric layer 130 is comprised of a second dielectric material. The first dielectric material and second dielectric material can be the same dielectric material, or they can be different dielectric materials. A frontside metal layer 135 is formed on top of the second dielectric layer 130. FIG. 4 illustrates that the frontside metal layer 135 has a comb profile, i.e., a horizontal section and a plurality of a protrusions/teeth 135T extending off the comb. The teeth/protrusions 135T of the frontside metal layer 135 extend into the valleys of the serpentine structure as illustrated in FIG. 4. The frontside metal layer 135 can be comprised of a second conductive metal. The first and second conductive metals can be the same conductive metal or different conductive metals.

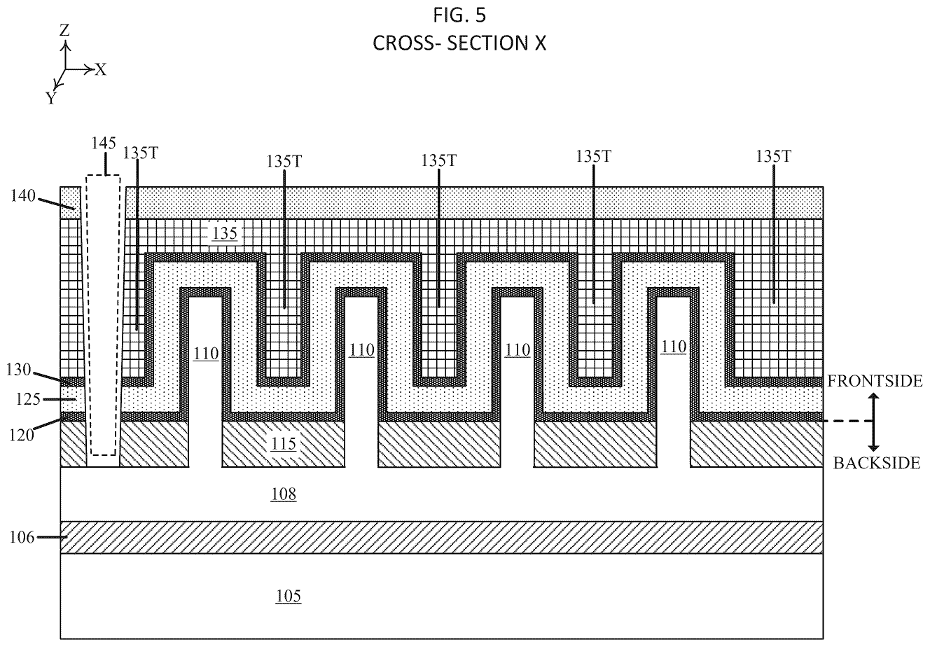

FIG. 5 illustrates the processing stage after the formation of a frontside electrode trench 145. A frontside interlayer dielectric layer 140 is formed on top of the frontside metal layer 135. A lithography layer (not shown) is formed on top of the frontside interlayer dielectric layer 140. The lithography layer (not shown) is patterned and a frontside electrode trench 145 is formed in the frontside interlayer dielectric layer 140, the frontside metal layer 135, the serpentine structure, and the shallow trench isolation layer 115. The lithography layer (not shown) is removed. The frontside electrode trench 145 exposes portions of the frontside metal layer 135, portions of one of the protrusions/teeth 135T of the frontside metal layer 135, the second dielectric layer 130, the serpentine metal layer 125, the first dielectric layer 125, and the shallow trench isolation layer 115. The frontside electrode trench 145 exposes a top surface of the second substrate 108, meaning that the frontside electrode trench 145 extends completely through the shallow trench isolation layer 115.

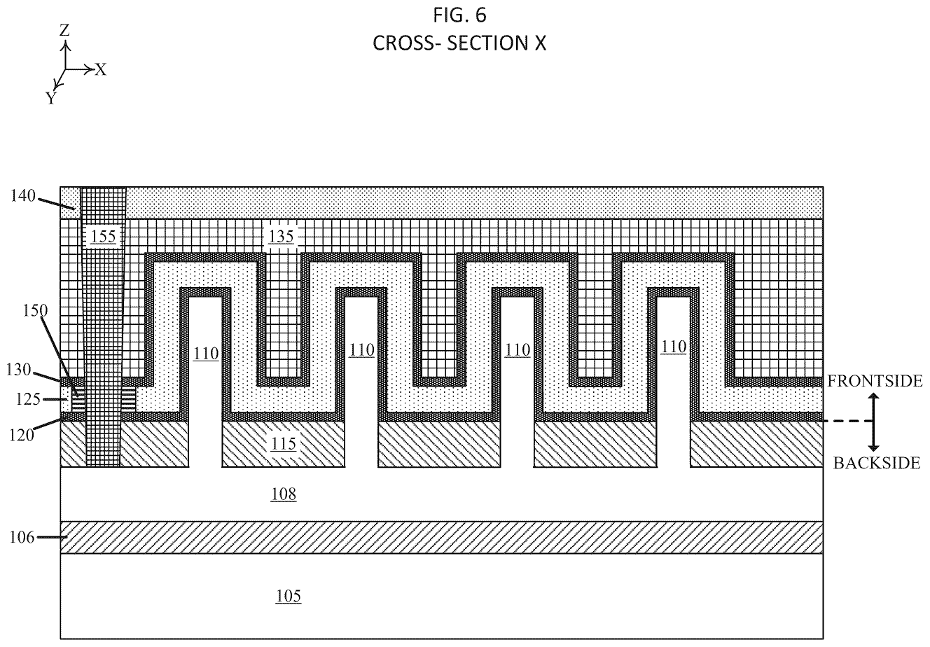

FIG. 6 illustrates the processing stage after the formation of a serpentine spacer 150 and the frontside electrode 155. The exposed area of the serpentine metal layer 125 (i.e., the portion exposed by the frontside electrode trench 145) is selectively etched/recessed to create an empty space/gap between the serpentine metal layer 125 and the frontside electrode trench 145. A serpentine spacer 150 is formed in the recessed area/gap created in the serpentine metal layer 125. A metallization process is utilized to fill the frontside electrode trench 145 with a conductive metal to form the frontside electrode 155. The frontside electrode 155 is in contact with the frontside metal layer 135 and is isolated from the serpentine metal layer 125 by the serpentine spacer 150. The bottom surface or backside surface of the frontside electrode 155 is in contact with the second substrate 108.

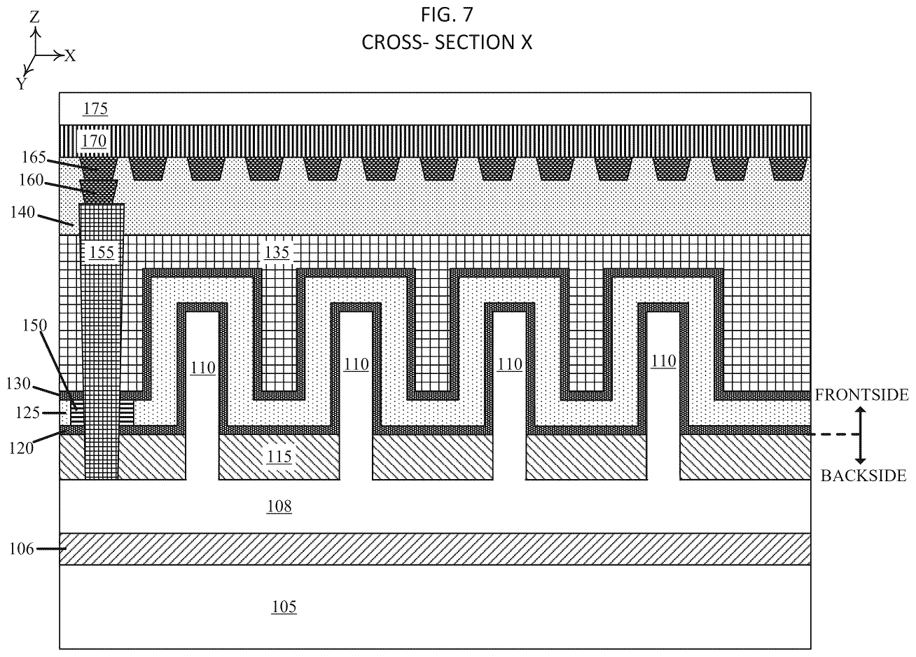

FIG. 7 illustrates the processing stage after additional processing. The height of the interlayer dielectric layer 140 is increased by adding additional dielectric material. A plurality of trenches (not shown) is formed in the frontside interlayer dielectric layer 140. A metallization process fills the plurality of trenches (not shown) with a conductive metal to form one or more connecting via(s) 160 (FIG. 7 illustrates one of the connecting via(s) 160) and a plurality of metal lines 165. The plurality of metal lines 165 can include power lines (VSS, VDD, ground), signal lines, clock lines, other types of metal lines, or a combination thereof. A frontside interconnect 170 is formed on top of the plurality of metal lines 165. The frontside interconnect 170 can include one or more layers/levels, one or more vias, and one or more metal lines. The frontside interconnect 170 is illustrated as a single layer for illustrative purposes only. Additionally, the one or more of the connecting via(s) 160 and the plurality of metal lines 165 can be part of the frontside interconnect 170. Carrier wafer 175 is formed on top of the frontside interconnect 170. The carrier wafer 175 allows for the flipping of the wafer (i.e., the FinFET region and the MIM region) to allow for backside processing of these devices.

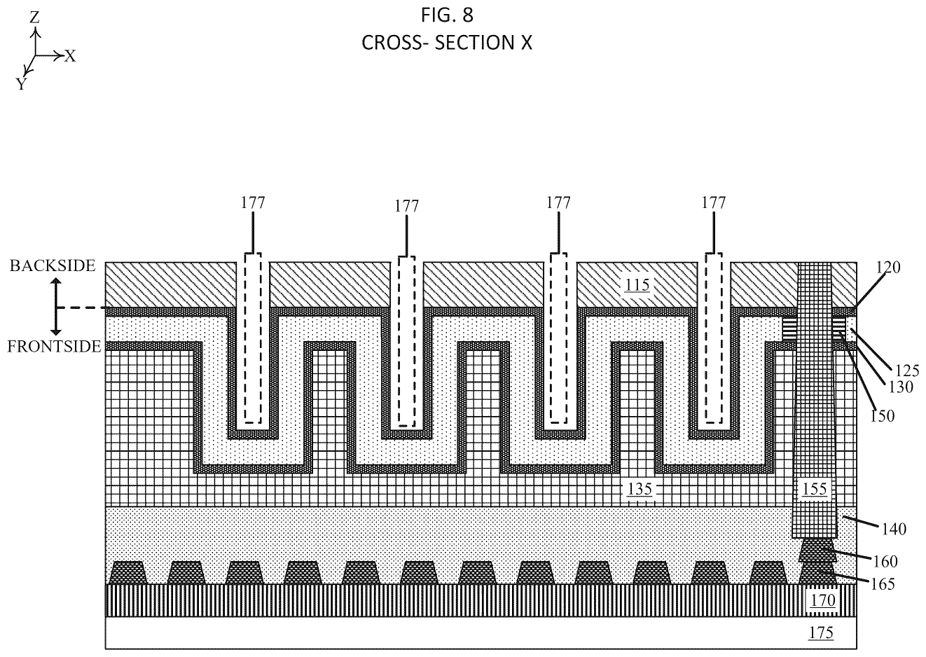

FIG. 8 illustrates a processing stage after initial backside processing. The first substrate 105, the etch stop 106, and the second substrate 108 are removed. The removal of the second substrate 108 exposes the backside surface of the shallow trench isolation layer 115. The removal of the second substrate 108 further exposes the backside surface of the frontside electrode 155. The removal of the second substrate 108 further removes fins 110. The removal of fins 110 creates valleys/empty spaces 177 within the serpentine structure as illustrated in FIG. 8. These valleys/empty spaces 177 extend from the backside surface of the shallow trench isolation layer 115 to the lowest point in the first dielectric layer 120 (or the side that is closest to the frontside interconnect 170).

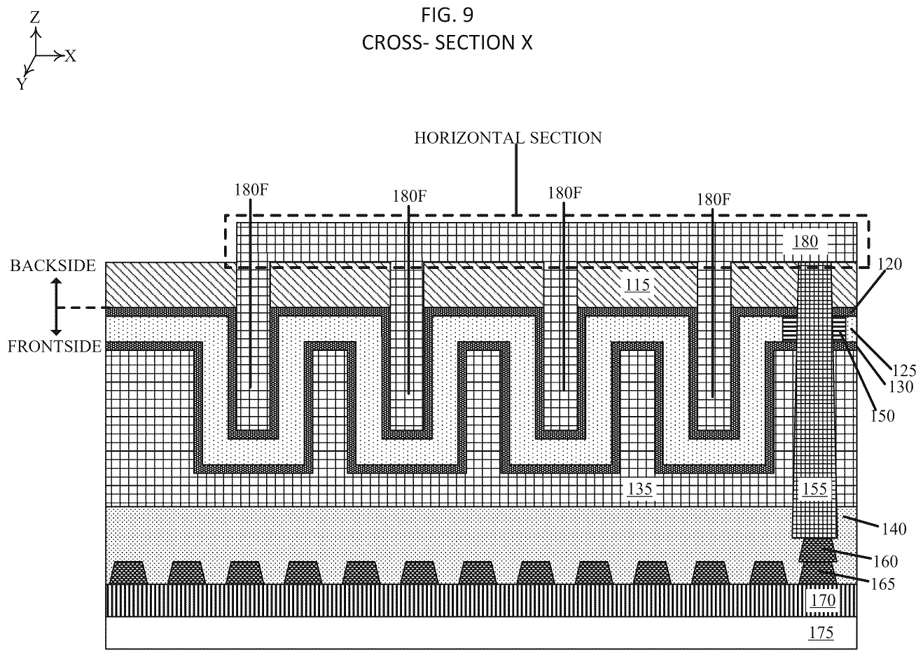

FIG. 9 illustrates a processing stage after formation of the backside metal layer 180. The backside metal layer 180 is formed on the backside surface of the shallow trench isolation layer 115. The backside metal layer 180 is patterned to remove excess and unnecessary portions of the metal layer. The backside metal layer 180 includes a horizontal section and a plurality of teeth/protrusions/fins 180F that extend off the horizontal section into the serpentine structure. The teeth/protrusions/fins 180F of the backside metal layer 180 replace the removed fins 110. The teeth/protrusions/fins 180F are in contact with a side surface of the shallow trench isolation layer 115 and in contact with the first dielectric layer 120. The serpentine structure (i.e., the first dielectric layer 120, the serpentine metal layer 125, and the second dielectric layer 130) is located between the protrusions/teeth 135T of the frontside metal layer 135 and the teeth/protrusions/fins 180F of the backside metal layer 180. Furthermore, the serpentine structure is located between the horizontal section of the frontside metal layer 135 and the teeth/protrusions/fins 180F of the backside metal layer 180. Based on the serpentine profile of the serpentine structure as illustrated by cross-section X, the protrusions/teeth 135T of the frontside metal layer 135 and the teeth/protrusions/fins 180F of the backside metal layer 180 extend into the profile of the serpentine structure. The horizontal section of the backside metal layer 180 is separated from the serpentine structure by the shallow trench isolation layer 115. The backside metal layer 180 and the teeth/protrusions/fins 180F are comprised of a third conductive metal. The third conductive metal can be the same material as either/both as the first conductive metal (i.e., the serpentine metal layer 125) and the second conductive metal (i.e., the frontside metal layer 135), or the third conductive metal can be different materials as either/both as the first conductive metal (i.e., the serpentine metal layer 125) and the second conductive metal (i.e., the frontside metal layer 135).

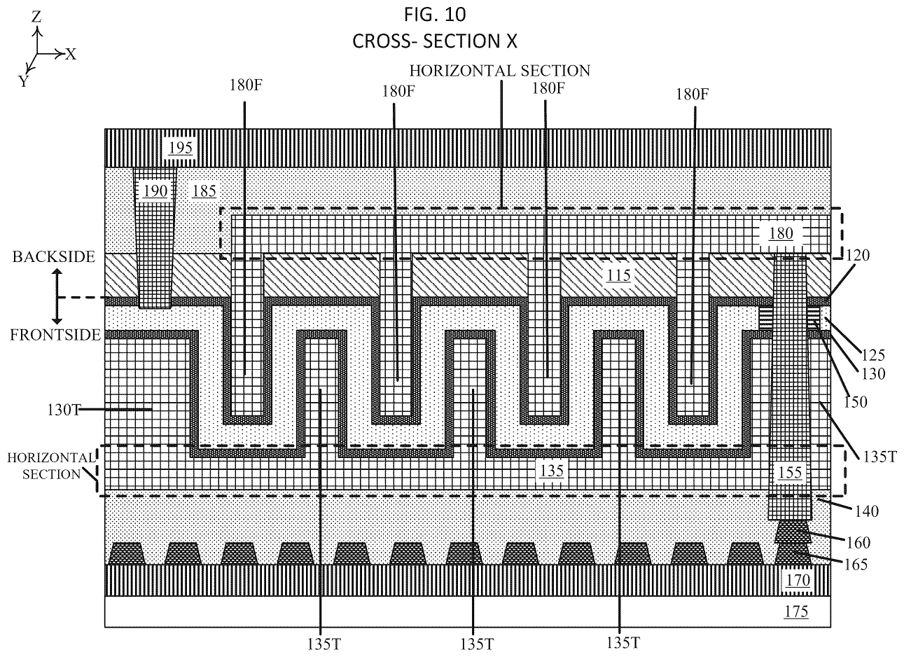

FIG. 10 illustrates the processing stage after additional processing. A backside interlayer dielectric layer 185 is formed on top of the backside metal layer 180 and on top of the shallow trench isolation layer 115. A lithography layer (not shown) is formed on top of the backside interlayer dielectric layer 185. The lithography layer (not shown) and the backside interlayer dielectric layer 185 are patterned to form a backside electrode trench (not shown). The backside electrode trench (not shown) exposes a surface of the serpentine metal layer 125. The backside electrode trench (not shown) does not connect to the backside metal layer 180. A metallization process fills the backside electrode trench (not shown) with a conductive metal to form the backside electrode 190. A backside interconnect 195 is formed on top of the backside electrode 190 and on the backside interlayer dielectric layer 185. The backside interconnect 195 can include one or more layers/levels, one or more vias, and one or more metal lines. The backside interconnect 195 is illustrated as a single layer for illustrative purposes only.

As stated above, the serpentine metal layer 125 is comprised of a first conductive metal material, the frontside metal layer 135, 135T is comprised of a second conductive metal material, and the backside metal layer 180, 180F is comprised of a third conductive metal material. The first, second, third conductive metal materials can be the same material, different materials, or a combination of being the same/different materials. For example, the first and second conductive metal materials can be the same material while the third conductive metal is a different material, or the second conductive metal and the third conductive metal can be the same material while the first conductive metal is a different material.

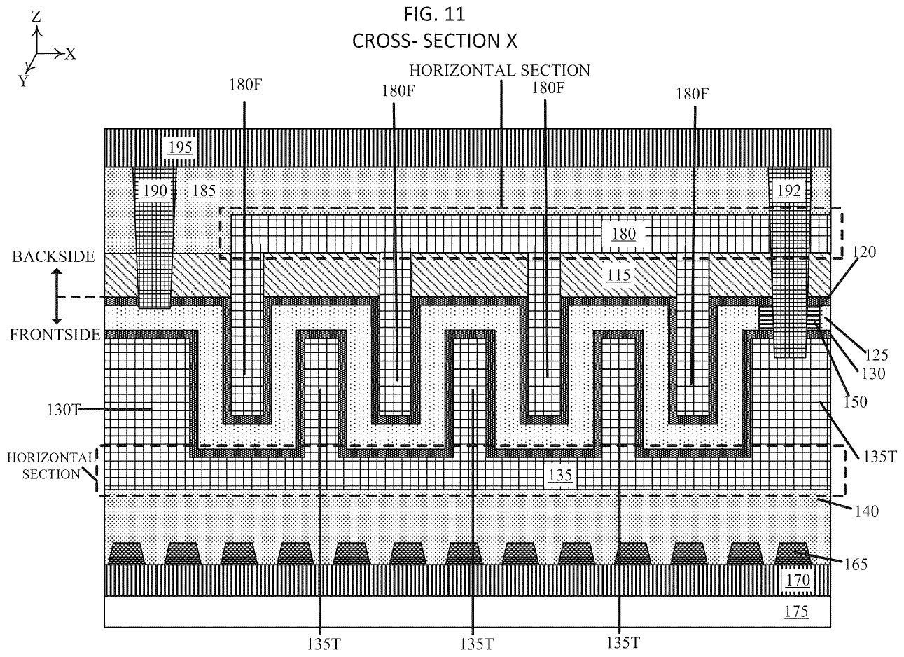

FIG. 11 illustrates a different wiring scenario for the MIM capacitance device. FIGS. 2-10 illustrate the scenario that includes a frontside electrode 155 and a backside electrode 190. FIG. 11 illustrates the scenario where the backside electrode 190 connects to the serpentine metal layer 125 and a second backside electrode 192 connects to the backside metal layer 180 and the frontside metal layer 135. The second backside electrode 192 is formed by a trench (not shown) that extends through the backside metal layer 180, the shallow trench isolation layer 115, the serpentine structure to expose the frontside metal layer 135. Serpentine spacer 150 are formed in the serpentine metal layer 125 and the trench (now shown) is filled with a conductive metal to form the second backside electrode 192. Serpentine spacers 150 isolate the second backside electrode 192 from the serpentine metal layer 125.

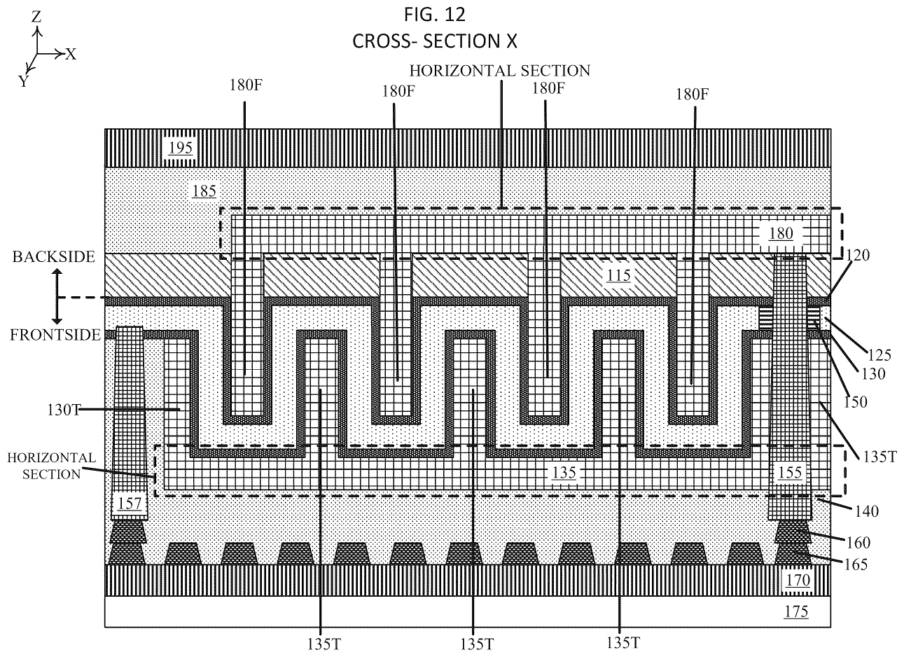

FIG. 12 illustrates a different wiring scenario for the MIM capacitance device. FIGS. 2-10 illustrate the scenario that includes a frontside electrode 155 and a backside electrode 190. FIG. 12 illustrates the scenario where the frontside electrode 155 is connected to the frontside metal layer 135 and the backside metal layer 180. A second frontside electrode 157 can be formed in the frontside interlayer dielectric layer 140, where the second frontside electrode 157 is connected to the serpentine metal layer 125.

A metal-insulator-metal (MIM) capacitor includes a serpentine structure that includes a first serpentine dielectric layer 120, a serpentine metal layer 125, and a second serpentine dielectric layer 130. The serpentine metal layer 125 is located between the first serpentine dielectric layer 120 and the second serpentine dielectric layer 130. A frontside metal layer 135 located on a first side of the serpentine structure, and the frontside metal layer 135, 135T extends into a plurality of valleys located first side of the serpentine structure. A backside metal layer 180 located on a second side of the serpentine structure and the backside metal layer 180, 180F extends into a plurality of valleys located on the second side of the serpentine structure.

The serpentine structure has a serpentine profile, and the serpentine profile creates a plurality of valleys on the first side and the second side of the serpentine structure. The frontside metal layer 120 includes a horizontal section and a plurality of protrusions 135T. Each of the plurality of protrusions 135T of the frontside metal layer 135 extends into one of the plurality of valleys located on the first side of the serpentine structure. The backside metal layer 180 includes a horizontal section and a plurality of protrusions 180F. The plurality of protrusions 180F of the backside metal layer extends 180 into one of the plurality of valleys located on the second side of the serpentine structure. A shallow trench isolation layer 115 located on the second side of the serpentine structure. The shallow trench isolation layer 115 is located between the serpentine structure and the horizontal section of the backside metal layer 180.

A metal-insulator-metal (MIM) capacitor includes a serpentine structure that includes a first serpentine dielectric layer 120, a serpentine metal layer 125, and a second serpentine dielectric layer 130. The serpentine metal layer 125 is located between the first serpentine dielectric layer 120 and the second serpentine dielectric layer 130. A frontside metal layer 135 located on a first side of the serpentine structure, and the frontside metal layer 135, 135T extends into a plurality of valleys located first side of the serpentine structure. A backside metal layer 180 located on a second side of the serpentine structure and the backside metal layer 180, 180F extends into a plurality of valleys located on the second side of the serpentine structure. A first electrode 155, 192 connected to the frontside metal layer 135 and the backside metal layer 180. A second electrode 190, 157 connected to the serpentine metal layer 125.

The serpentine structure has a serpentine profile, and the serpentine profile creates a plurality of valleys on the first side and the second side of the serpentine structure. The frontside metal layer 120 includes a horizontal section and a plurality of protrusions 135T. Each of the plurality of protrusions 135T of the frontside metal layer 135 extends into one of the plurality of valleys located on the first side of the serpentine structure. The backside metal layer 180 includes a horizontal section and a plurality of protrusions 180F. The plurality of protrusions 180F of the backside metal layer extends 180 into one of the plurality of valleys located on the second side of the serpentine structure. A shallow trench isolation layer 115 located on the second side of the serpentine structure. The shallow trench isolation layer 115 is located between the serpentine structure and the horizontal section of the backside metal layer 180.

The first electrode 155 is located in a frontside region of the MIM capacitor, and the second electrode 190 is located in a backside region of the MIM capacitor.

The first electrode 192 is located in a backside region of the MIM capacitor, and the second electrode 190 is located in the backside region of the MIM capacitor.

The first electrode 155 is located in a frontside region of the MIM capacitor, and the second electrode 157 is located in frontside region of the MIM capacitor.

A microelectronic structure includes a FinFET device located in a FinFET region on a chip and a metal-insulator-metal (MIM) capacitor located in a MIM region on the chip. The MIM capacitor includes a serpentine structure that includes a first serpentine dielectric layer 120, a serpentine metal layer 125, and a second serpentine dielectric layer 130. The serpentine metal layer 125 is located between the first serpentine dielectric layer 120 and the second serpentine dielectric layer 130. A frontside metal layer 135 located on a first side of the serpentine structure, and the frontside metal layer 135, 135T extends into a plurality of valleys located first side of the serpentine structure. A backside metal layer 180 located on a second side of the serpentine structure and the backside metal layer 180, 180F extends into a plurality of valleys located on the second side of the serpentine structure. A first electrode 155, 192 connected to the frontside metal layer 135 and the backside metal layer 180. A second electrode 190, 157 connected to the serpentine metal layer 125.

The serpentine structure has a serpentine profile, and the serpentine profile creates a plurality of valleys on the first side and the second side of the serpentine structure. The frontside metal layer 120 includes a horizontal section and a plurality of protrusions 135T. Each of the plurality of protrusions 135T of the frontside metal layer 135 extends into one of the plurality of valleys located on the first side of the serpentine structure. The backside metal layer 180 includes a horizontal section and a plurality of protrusions 180F. The plurality of protrusions 180F of the backside metal layer extends 180 into one of the plurality of valleys located on the second side of the serpentine structure.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A metal-insulator-metal (MIM) capacitor comprising:
a serpentine structure that includes a first serpentine dielectric layer, a serpentine metal layer, and a second serpentine dielectric layer; wherein the serpentine metal layer is located between the first serpentine dielectric layer and the second serpentine dielectric layer;
a frontside metal layer located on a first side of the serpentine structure, wherein the frontside metal layer extends into a plurality of valleys located first side of the serpentine structure; and
a backside metal layer located on a second side of the serpentine structure, wherein the backside metal layer extends into a plurality of valleys located on the second side of the serpentine structure.

2. The MIM capacitor of claim 1, wherein the serpentine structure has a serpentine profile, wherein the serpentine profile creates a plurality of valleys on the first side and the second side of the serpentine structure.

3. The MIM capacitor of claim 2, wherein the frontside metal layer includes a horizontal section and a plurality of protrusions.

4. The MIM capacitor of claim 3, wherein each of the plurality of protrusions of the frontside metal layer extends into one of the plurality of valleys located on the first side of the serpentine structure.

5. The MIM capacitor of claim 4, wherein the backside metal layer includes a horizontal section and a plurality of protrusions.

6. The MIM capacitor of claim 5, wherein the plurality of protrusions of the backside metal layer extends into one of the plurality of valleys located on the second side of the serpentine structure.

7. The MIM capacitor of claim 6, further comprising:
a shallow trench isolation layer located on the second side of the serpentine structure.

8. The MIM capacitor of claim 7, wherein the shallow trench isolation layer is located between the serpentine structure and the horizontal section of the backside metal layer.

9. A metal-insulator-metal (MIM) capacitor comprising:
a serpentine structure that includes a first serpentine dielectric layer, a serpentine metal layer, and a second serpentine dielectric layer; wherein the serpentine metal layer is located between the first serpentine dielectric layer and the second serpentine dielectric layer;
a frontside metal layer located on a first side of the serpentine structure, wherein the frontside metal layer extends into a plurality of valleys located first side of the serpentine structure;
a backside metal layer located on a second side of the serpentine structure, wherein the backside metal layer extends into a plurality of valleys located on the second side of the serpentine structure;
a first electrode connected to the frontside metal layer and the backside metal layer; and
a second electrode connected to the serpentine metal layer.

10. The MIM capacitor of claim 9, wherein the serpentine structure has a serpentine profile, wherein the serpentine profile creates a plurality of valleys on the first side and the second side of the serpentine structure.

11. The MIM capacitor of claim 10, wherein the frontside metal layer includes a horizontal section and a plurality of protrusions, and wherein each of the plurality of protrusions of the frontside metal layer extends into one of the plurality of valleys located on the first side of the serpentine structure.

12. The MIM capacitor of claim 11, wherein the backside metal layer includes a horizontal section and a plurality of protrusions, wherein the plurality of protrusions of the backside metal layer extends into one of the plurality of valleys located on the second side of the serpentine structure.

13. The MIM capacitor of claim 12, further comprising:
a shallow trench isolation layer located on the second side of the serpentine structure.

14. The MIM capacitor of claim 13, wherein the shallow trench isolation layer is located between the serpentine structure and the horizontal section of the backside metal layer.

15. The MIM capacitor of claim 9, wherein the first electrode is located in a frontside region of the MIM capacitor, and the second electrode is located in a backside region of the MIM capacitor.

16. The MIM capacitor of claim 9, wherein the first electrode is located in a backside region of the MIM capacitor, and the second electrode is located in the backside region of the MIM capacitor.

17. The MIM capacitor of claim 9, wherein the first electrode is located in a frontside region of the MIM capacitor, and the second electrode is located in frontside region of the MIM capacitor.

18. A microelectronic structure comprising:
a FinFET device located in a FinFET region on a chip;
a metal-insulator-metal (MIM) capacitor located in a MIM region on the chip, wherein the MIM capacitor is comprised of:
a serpentine structure that includes a first serpentine dielectric layer, a serpentine metal layer, and a second serpentine dielectric layer; wherein the serpentine metal layer is located between the first serpentine dielectric layer and the second serpentine dielectric layer;
a frontside metal layer located on a first side of the serpentine structure, wherein the frontside metal layer extends into a plurality of valleys located first side of the serpentine structure;
a backside metal layer located on a second side of the serpentine structure, wherein the backside metal layer extends into a plurality of valleys located on the second side of the serpentine structure;
a first electrode connected to the frontside metal layer and the backside metal layer; and
a second electrode connected to the serpentine metal layer.

19. The microelectronic structure of claim 18, wherein the serpentine structure has a serpentine profile, wherein the serpentine profile creates a plurality of valleys on the first side and the second side of the serpentine structure.

20. The microelectronic structure of claim 19, wherein the frontside metal layer includes a horizontal section and a plurality of protrusions, wherein each of the plurality of protrusions of the frontside metal layer extends into one of the plurality of valleys located on the first side of the serpentine structure, wherein the backside metal layer includes a horizontal section and a plurality of protrusions, wherein the plurality of protrusions of the backside metal layer extends into one of the plurality of valleys located on the second side of the serpentine structure.
